(19) United States
(12) Patent Application Publication
(10) Pub. No.: US 2013/0242473 A1
(43) Pub. Date: Sep. 19, 2013

(54) ELECTRONIC DEVICE

(71) Applicant: JI-FENG QIU, Shenzhen City (CN)

(72) Inventor: JI-FENG QIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/596,125

(22) Filed: Aug. 28, 2012

(30) Foreign Application Priority Data
Mar. 15, 2012 (CN) 201210067661.7

(51) Int. Cl. H05K 5/00

(52) U.S. Cl. 361/679.01

(57) ABSTRACT

An electronic device includes a first housing, a second housing, a component member, a screw, and a gathering post. The first housing defines a through hole. The second housing combines with the first housing to form a receiving space. The component member is received in the receiving space. The screw passes through the through hole of the first housing to screw in a predetermined position of the component member. The gathering post gathers filings falling from the component member when the screw is screwed in the component member.

### BACKGROUND

1. Technical Field

The present disclosure relates to an electronic device.

2. Description of Related Art

The combination of a screw and a nut cooperatively forming a fastening structure to fasten a component member is widely used. For example, when an assembly member is fasten to an electronic device with a plastic housing by the above fastening structure, the nut is commonly secured to a plastic post of the housing by hot melting. However, the hot melting method is costly. Further, when the hot melting temperature is not high enough to make the post melt, the post does not form properly and it is difficult to secure the nut to the housing.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an electronic device.

FIG. 2 is an explored view o f the electronic device in FIG. 1.

FIG. 3 is an inverted view of the electronic device in FIG 2.

FIG. 4 is an isometric view of the electronic device without a second housing of the electronic device in FIG. 1.

FIG. 5 is a cross-sectional view of the electronic device in FIG. 1.

### DETAILED DESCRIPTION

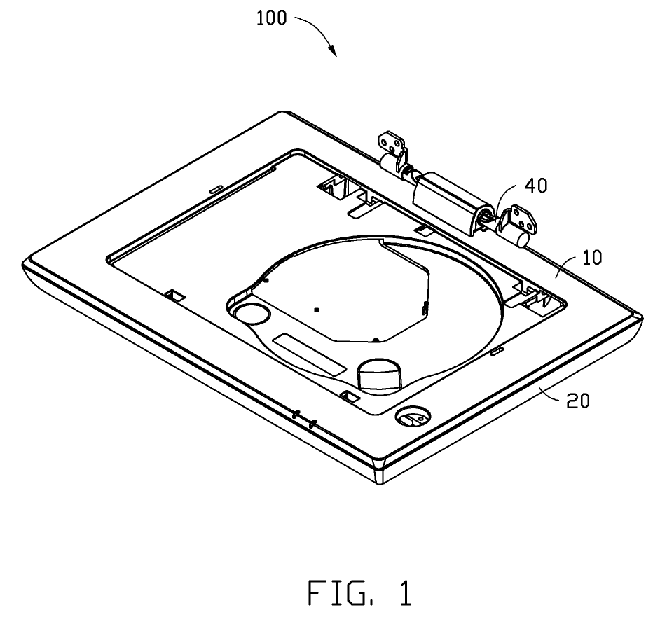

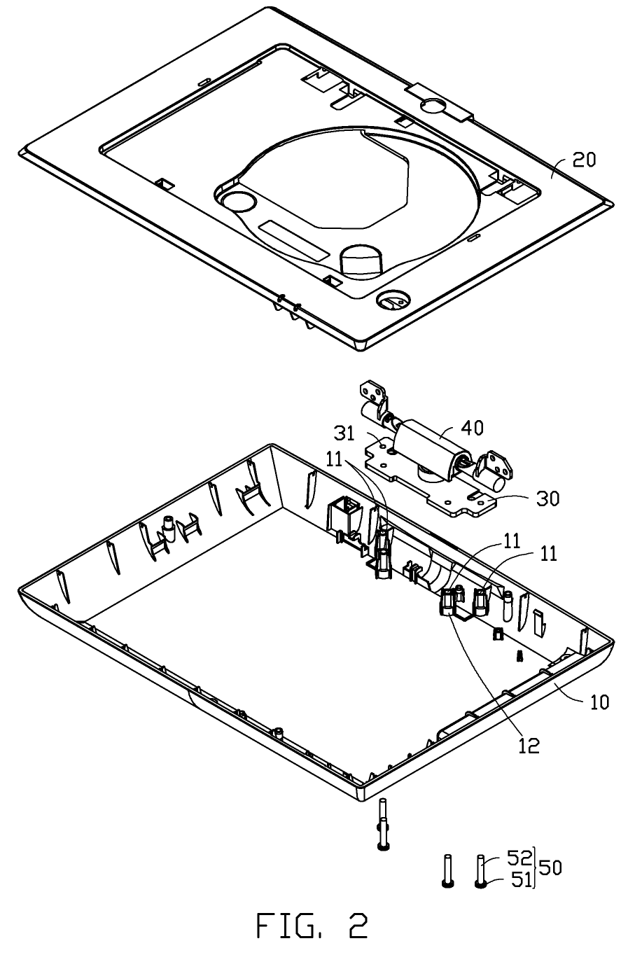

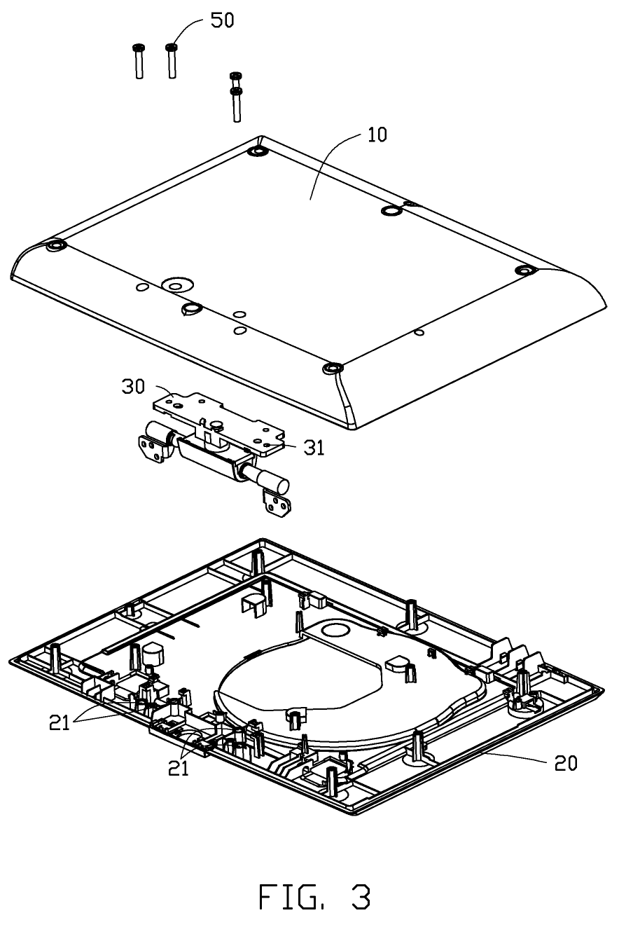

Referring to FIGS. 1-3, the electronic device 100 includes a first housing 10, a second housing 20, a component member 30, and a rotating mechanism 40. The first housing 10 combines the second housing 20 to form a receiving space. The component member 30 is received between the first housing 10 and the second housing 20, and secured on the first housing 10 via a plurality of screws 50. The rotating mechanism 40 is secured to the component member 30, and the rotating mechanism 40 passes through the second housing 20.

The screw 50 includes a disk-like head 51 and a columnar shaft 51 connected to the head 51.

The component member 30 is made of metal and is substantially a rectangular board. A plurality of first through holes 31 are defined in the component member 30. In the embodiment, the number of the first through holes 31 is four. The first through holes 31 are defined in four predetermined positions of the component member 30. The diameters of first through holes 31 are smaller than the diameters of the shafts 52.

The rotating mechanism 40 is secured to the middle of the component member 30, to rotatably connect to an object (not shown).

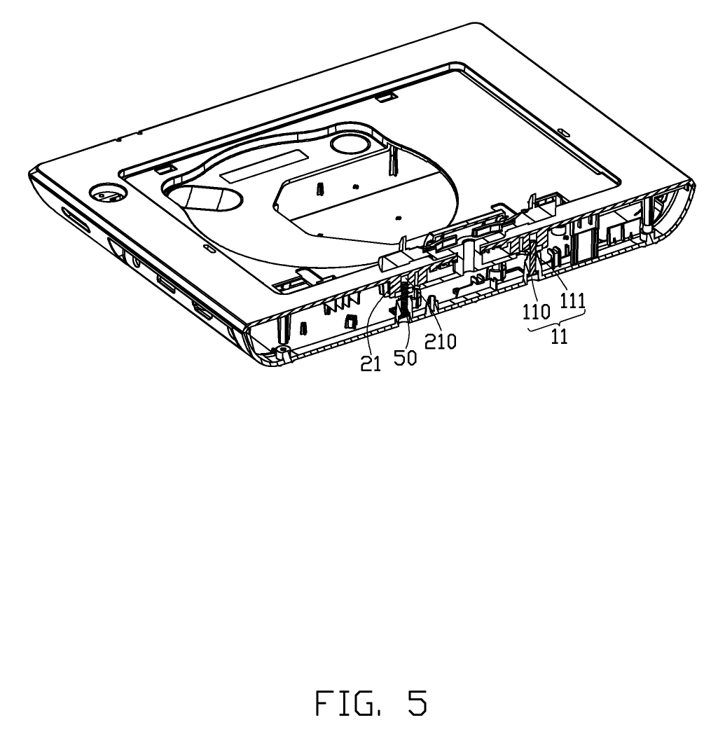

Four receiving posts 12 protrude from the first housing 10 and face the second housing 20. Each post 12 corresponds with each of the first through holes 31. Four second through holes 11 are defined to pass through the first housing 10 and each of the post 12. Each second through hole 11 includes a first portion 110 (see FIG. 5), and a second portion 111 (see FIG. 5). The first portion 110 is matched to the head 51. The second portion 111 is matched to the shaft 52.

Four gathering posts 21 protrude from the second housing 20 and face the first housing 10. Each gathering post 21 defines a gathering groove 210 (see FIG. 5). Each gathering groove 210 is concentric with each of the first through holes 31.

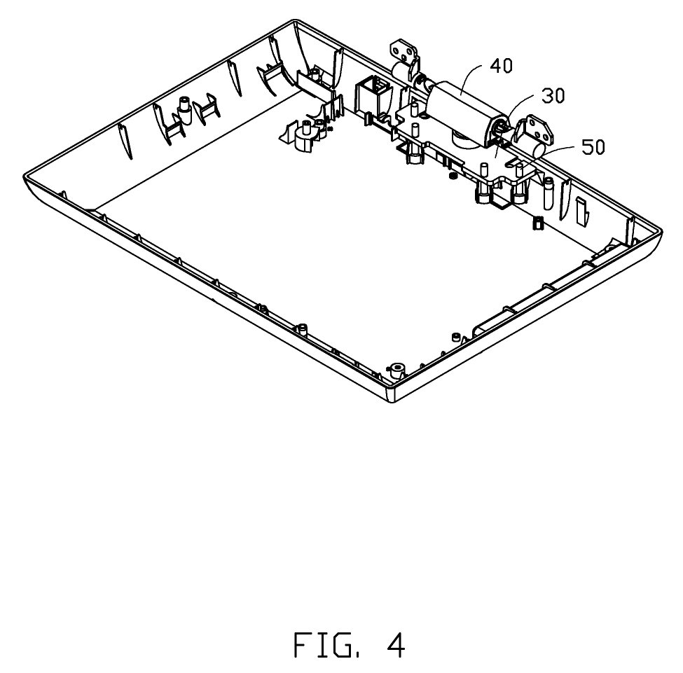

Referring to FIGS. 4-5, to secure the component member 30 to the first housing 10 is described as below. First, the shaft 52 of each screw 50 is passed through the receiving groove 11. Second, the first housing 10 is placed in a plane, the component 30 is placed in the first housing 10, the shaft 52 contacts the component member 30, and the shaft 52 is concentric with the through hole 31; the second housing 20 is covered on the first housing 10, and the gathering groove 210 is concentric with shaft 52 and the through hole 31 through hole 11. Third, the screw 50 is screwed in the component member 30 by a screw tool (not shown), and the shaft 52 passes through the assembly member 30 to locate in the gathering groove 210. When the screw 50 is being screwed into the component member 30, filings may fall from the component member 30, and the filings are gathered in the gathering groove 210 that electronic device 100 is protected against filings. At this time, the assembly member 30 is secured to the first housing 10.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a first housing defining a first through hole;
a second housing combining with the first housing to form a receiving space;
a component member received in the receiving space;
a screw passing through the through hole of the first housing to screw in a predetermined position of the component member; and
a gathering post to gather filings falling from the component member when the screw is screwed in the component member, to enable the electronic device to be protected against filings.

2. The electronic device of claim 1, wherein the gathering post protrudes from the second housing and faces the first housing, the gathering post corresponds with the predetermined position.

3. The electronic device of claim 2, wherein the gathering post defines a gathering groove to gather the filings.

4. The electronic device of claim 1, wherein the predetermined position defines a second through hole, the screw is screwed in the through hole.

5. The electronic device of claim 1, wherein a receiving post protrudes from the first housing and faces the second housing, the first through holes passes through the first housing and the receiving post.

6. The electronic device of claim 1, wherein the first through holes matches with the screw.

7. An electronic device comprising:
a housing;
a component member received in the housing;
a screw screwed in a predetermined position of the component member; and
a gathering post to gather filings generated by the screw being screwed in the component member, to enable the housing to be protected against filings.

8. The electronic device of claim 7, wherein the gathering post protrudes from the housing, the gathering post corresponds the predetermined position.

9. The electronic device of claim 7, wherein the gathering post defines a gathering groove to gather the filings.

10. The electronic device of claim 7, wherein the predetermined position defines a second through hole, the screw is screwed in the second through hole.

11. The electronic device of claim 7, wherein a receiving post protrudes from the housing and faces the component member, a first through holes is defined to pass through the housing and the receiving post to allow the screw to be inserted into the housing to screw in the component member.
